(19) United States
(12) Patent Application Publication
(10) Pub. No.: US 2009/0109620 A1
(43) Pub. Date: Apr. 30, 2009

(54) HEAT-DISSIPATING DEVICE OF PORTABLE ELECTRONIC APPARATUS

(76) Inventors: Cheng-Tu WANG, Taipei (TW); Pang-Hung Liao, Taipei (TW); Kuan-Ming Lai, Taipei (TW)

Correspondence Address: HDLS Patent & Trademark Services, P.O. BOX 220746, CHANTILLY, VA, 20153-0746, US

(21) Appl. No.: 11/930,864

(22) Filed: Oct. 31, 2007

(51) Int. Cl. H05K 7/20

(52) U.S. Cl. 361/697

(57) ABSTRACT

A heat-dissipating device of a portable electronic apparatus includes a heat-conducting plate disposed on a heat-generating element. One end of a heat-conducting pipe is disposed on the heat-conducting plate, and the other end of the heat-conducting pipe is disposed on a surface of a power generator to form a high-temperature source. The opposite surface of the power generator is fixedly disposed on a heat-dissipating body to form a low-temperature source. A heat-dissipating fan is provided on one side of the heat-dissipating body. The positive and negative lines of the heat-dissipating fan are electrically connected to the positive and negative lines of the power generator. Via the above arrangement, after the heat-conducting plate conducts the heat source to the heat-conducting pipe to perform a heat exchange, the heat source is then conducted to the other end of the heat-conducting pipe, so that the surface of the power generator contacting the end of the heat-conducting pipe becomes a high-temperature source, while the other surface acts as a low-temperature source. Thus, the heat due to the temperature difference can be converted into electricity correspondingly, thereby providing the necessary power for the operation of the heat-dissipating fan. Therefore, a self-powered heat-dissipating device can be achieved.

### BACKGROUND OF THE INVENTION

1. Field of the Invention

The present invention relates to a heat-dissipating device, and in particular to a heat-dissipating device of a portable electronic apparatus that can be self-powered by utilizing thermoelectric materials.

2. Description of Prior Art

The technology of electronic elements is progressing greatly for these years. Especially, the central processor used in a computer is made more and more compact while the operating performance and efficiency thereof are enhanced continuously. However, the heat generated by a power-consuming operation of the electronic element is thus accommodated so fast that the heat-dissipating rate is insufficient. If the heat of the central processor cannot be conducted or dissipated rapidly, an overheated phenomenon may be caused. As a result, the computer may crash and the central processor may even burn down.

There are various kinds of heat-dissipating devices. In one version, a fan is fixed on the casing of an electronic apparatus and is designed to dissipate the hot air within the casing by mans of air circulation and further introducing external air that is colder than the internal air, thereby dissipating the heat generated by the operation of the electronic elements. In another version, a heat dissipator for dissipating the heat source generated by the electronic element includes a base and a set of heat-dissipating pieces connected on a surface of the base to conduct the heat. The set of heat-dissipating pieces are fixed on the surface of the electronic element via the base to conduct the heat, thereby absorbing the heat generated by the electronic element and then radiating the heat to ambient air. Of course, in these heat dissipators, the fan can be disposed on the heat-dissipating pieces to enhance the heat-dissipating rate of the heat-dissipating pieces. Therefore, it is an important issue to improve the heat-dissipating efficiency of the above-mentioned heat-dissipating device.

According to the above, in order to solve the above-mentioned drawbacks, the inventor proposes the present invention based on his expert experience and deliberate research.

### SUMMARY OF THE INVENTION

The present invention is to provide a heat-dissipating device of a portable electronic apparatus. The heat-dissipating device includes a heat-conducting plate disposed above a heat-generating element. One end of a heat-conducting pipe is disposed on the heat-conducting plate, and the other end of the heat-conducting pipe is disposed on a surface of a power generator to form a high-temperature source. The opposite surface of the power generator is fixedly provided on a heat-dissipating body to form a low-temperature source. The power generator is made of a thermoelectric material, by which the heat energy caused by the temperature difference can be converted into electricity. A heat-dissipating fan is provided on one side of the heat-dissipating body. The positive and negative lines of the heat-dissipating fan are electrically connected to the positive and negative lines of the power generator.

Via the above arrangement, after the heat-conducting plate conducts the heat source to the heat-conducting pipe to perform a heat exchange, the heat source is then conducted to the other end of the heat-conducting pipe, so that the surface of the power generator contacting the end of the heat-conducting pipe becomes a high-temperature source, while the other surface acts as a low-temperature source. Thus, the heat due to the temperature difference can be converted into electricity, thereby providing the necessary power for the operation of the heat-dissipating fan. Therefore, a self-powered heat-dissipating device can be achieved.

### BRIEF DESCRIPTION OF THE DRAWINGS

FIG. 1 is an exploded perspective view showing a portion of the heat-dissipating device of the present invention;

FIG. 2 is an assembled view showing the external appearance of the heat-dissipating device of the present invention;

FIG. 3 is a top view showing the heat-dissipating device of the present invention being disposed on a heat-generating element;

FIG. 4 is a side cross-sectional view showing the heat-dissipating device of the present invention being disposed on a heat-generating element; and

FIG. 5 is an assembled view showing the external appearance of the heat-dissipating device in accordance with another embodiment of the present invention.

### DETAILED DESCRIPTION OF THE INVENTION

The detailed description and technical contents of the present invention will be made with reference to the accompanying drawings. However, it should be understood that the drawings are illustrative only but not to limit the present invention.

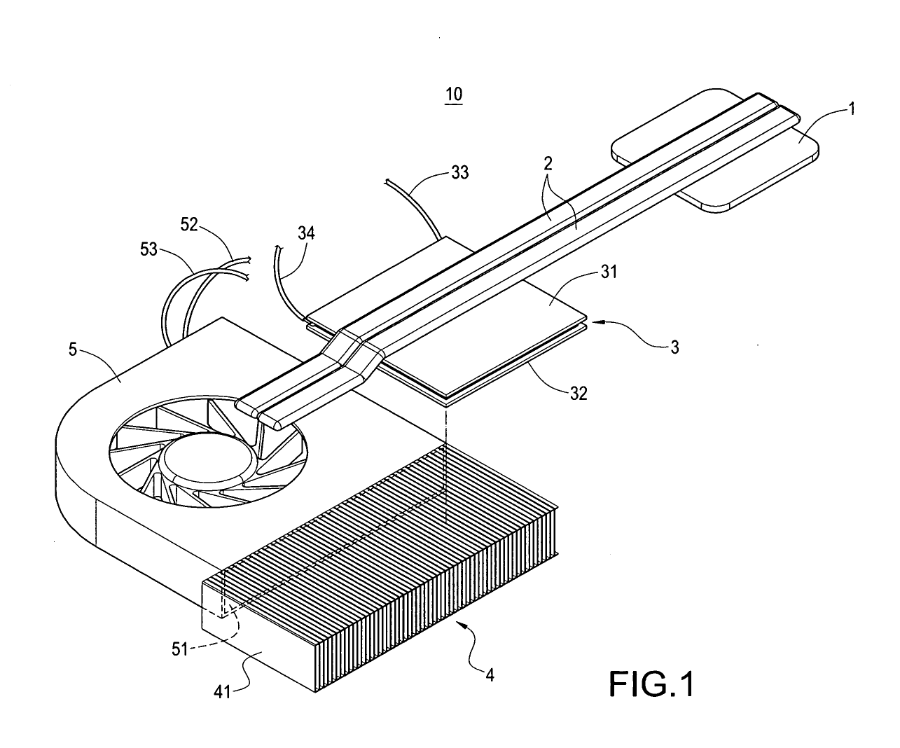

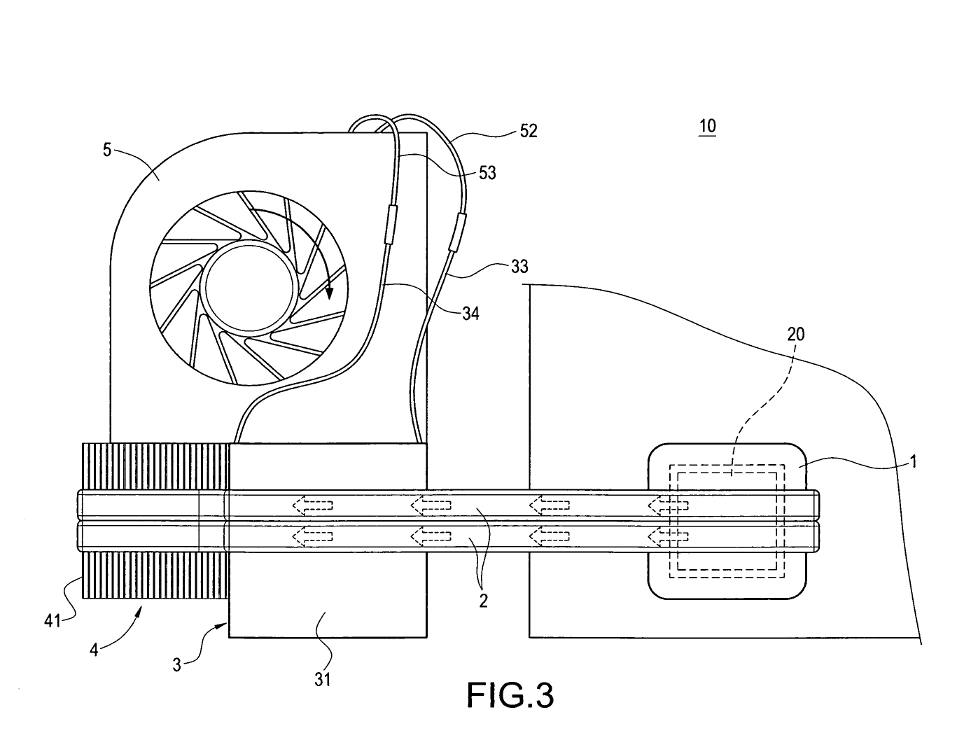

The present invention relates a heat-dissipating device of a portable electronic apparatus. With reference to FIG. 1, the present invention is directed to a heat-dissipating device 10 that can be used in an electronic apparatus such as a Note Book, PDA or game player. The heat-dissipating device 10 includes a heat-conducting plate 1 disposed on a heat-generating element. The heat-conducting plate 1 is a plate made of metallic materials or composite materials having high heat conductivity, and can be disposed on the heat-generating element 20 (FIG. 3) such as a hard disk or CPU. One end of a heat-conducting pipe 2 is disposed on the heat-conducting plate 1. In the present embodiment, two heat-conducting pipes 2 are juxtaposed. The interior of the heat-conducting pipe 2 is provided with a capillary structure and a working fluid. The actions of the capillary structure and the working fluid can generate an effect of conducting heat. The other end of the heat-conducting pipe 2 is provided on a surface of a power generator 3. Of course, as shown in the present embodiment, it can protrude beyond the exterior of the power generator 3 to abut against the top surface of each heat-dissipating fin 41 of a heat-dissipating body 4. In this way, the heat of the heat-conducting pipe 2 can be dissipated partially by means of each heat-dissipating fin 41.

In the present invention, the power generator 3 is a P-N semiconductor that is made of thermoelectric materials. The so-called thermoelectric material is one capable of converting the heat energy into electricity by means of a temperature difference. One surface of the power generator 3 is connected with a high-temperature heat-conducting piece 31, and the other surface is connected with a low-temperature heat-conducting piece 32. The power generator 3 converts the heat energy generated by the temperature difference between the high-temperature heat-conducting piece 31 and the low-temperature heat-conducting piece 32 into electricity correspondingly based on the principle of heat-electricity conversion. Therefore, the other end of the heat-conducting pipe 2 is fixedly provided on the high-temperature heat-conducting piece 31 of the power generator 3.

With reference to FIG. 1, the low-temperature heat-conducting piece 32 of the power generator 3 is provided thereon with a heat-dissipating body 4. The heat-dissipating body 4 can be an aluminum-extruded heat-dissipating body (not shown) or a laminated heat-dissipating body. In the present embodiment, the laminated heat-dissipating body 4 is constituted by stacking a plurality of heat-dissipating fins 41. The heat-dissipating body 4 is formed with a flowing path 42 between the two heat-dissipating fins 41. A heat-dissipating fan 5 is provided at the side of the heat-dissipating body 4 corresponding to the flowing path 42. The heat-dissipating fan 5 can be a centrifugal fan having a blowing port 51. The blowing port is attached to the side of the heat-dissipating body to face the flowing path 42. The positive and negative lines 52, 53 of the heat-dissipating fan 5 are electrically connected with the positive and negative lines 33, 34 of the power generator 3.

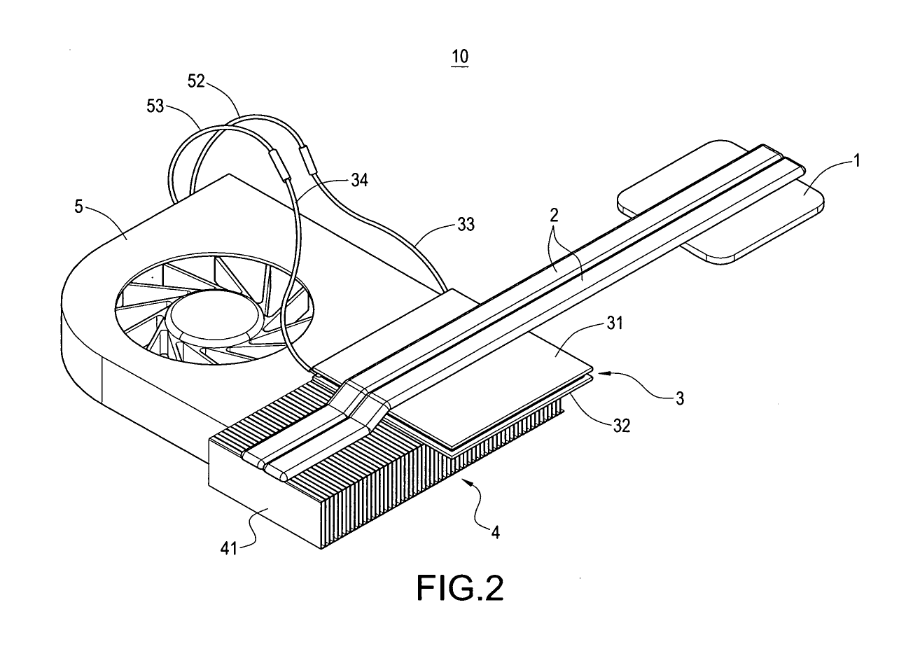

With reference to FIG. 2, when the present invention is used in a portable electronic apparatus, the heat-conducting plate 1 of the heat-dissipating device 10 is disposed on the heat-generating element 20. One end of the heat-conducting pipe 2 is located on the heat-conducting plate 1. The other end of the heat-conducting pipe 2 is fixed on the high-temperature heat-conducting piece 31 of the power generator 3, while the low-temperature heat-conducting piece 32 of the power generator 3 is mounted on the heat-dissipating body 4.

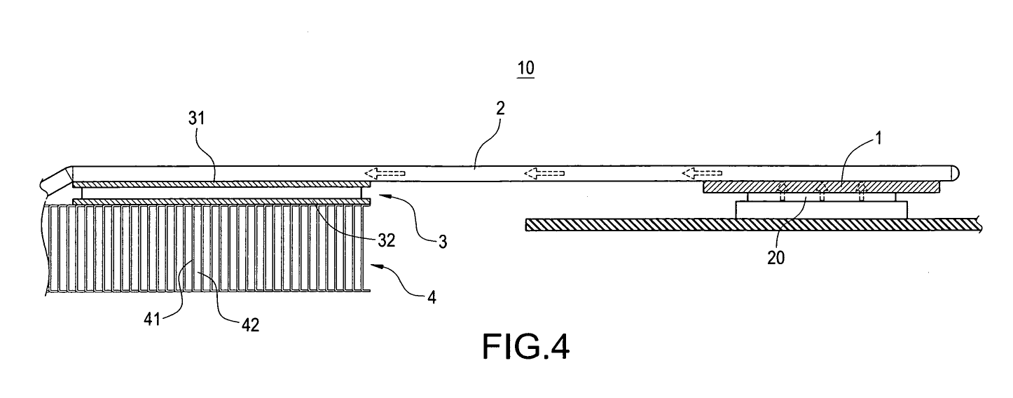

With reference to FIGS. 3 and 4, when the heat-generating element 20 is operated, the heat source generated will be conducted on the heat-conducting plate 1. The heat-conducting plate 1 exchanges the heat with the heat-conducting plate 2. With the working fluid and the capillary structure within the heat-conducting pipe 2, the heat source can be conducted into the heat-conducting pipe 2 and then conducted to the other end thereof. As a result, the high-temperature heat-conducting piece 31 of the power generator 3 contacting one end of the heat-conducting pipe 2 becomes a high-temperature source, while the low-temperature heat-conducting piece 32 on the other surface still acts as a low-temperature source because it does not receive the heat source. At this time, the power generator 3 generates electricity correspondingly via the temperature difference, thereby providing the necessary power for the operation of the heat-dissipating fan 5. The wind generated by the operation of the heat-dissipating fan 5 blows from the blowing port 51 toward the heat-dissipating body 4. As a result, the low-temperature heat-conducting piece 32 abutting against the heat-dissipating body 4 can be kept as a low-temperature source continuously.

Therefore, when the heat-generating element 20 operates continuously, the high-temperature heat-conducting piece 31 of the power generator 3 will be kept as a high-temperature source. Also, when the heat-dissipating fan 5 is powered to operate continuously to keep the heat-dissipating body 4 to a low temperature, the low-temperature heat-conducting piece 32 of the power generator 3 will be also kept as a low-temperature source. Until the heat-generating element 20 stops operating, the high-temperature heat-conducting piece 31 cannot be kept as a high-temperature source, so that there is no temperature difference available to be converted into electricity. Thus, the heat-dissipating fan 5 stops operating accordingly.

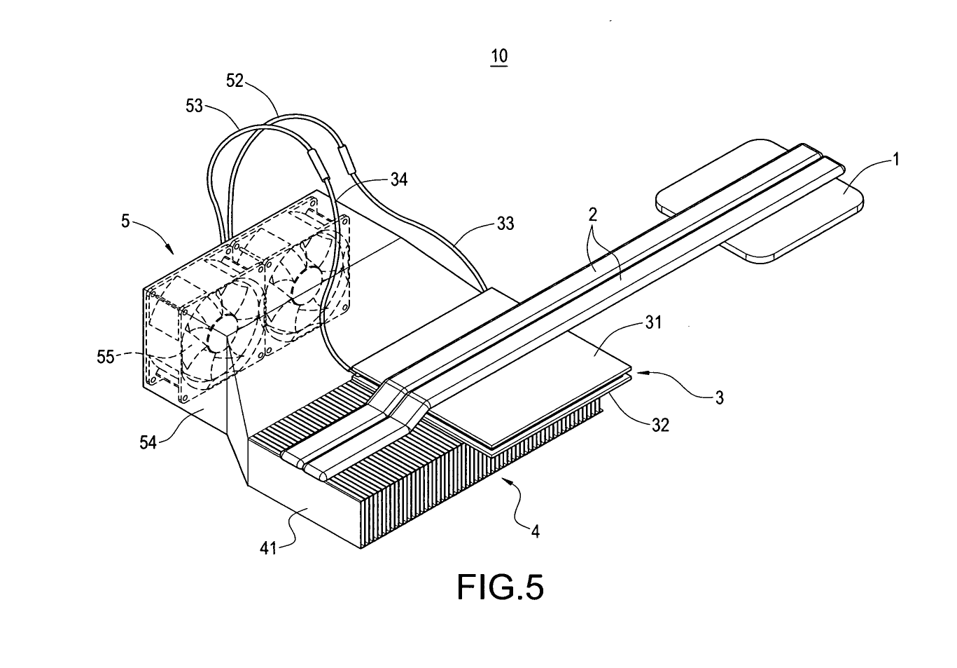

With reference to FIG. 5, in addition to the above embodiment, the heat-dissipating fan 5 of the present invention can be, as shown in the present embodiment, constituted of an air-guiding cover 54 and two axial impeller 55 fixedly connected to one end of the air-guiding cover 54. The blowing port 51 is formed on one end of the air-guiding cover 54 away from the axial impeller 55. Further, the blowing port 51 is connected to the side corresponding to the flowing path 42 of the heat-dissipating body 4 (FIG. 4). Via the above arrangement, the same effect as the previous embodiment can be achieved.

According to the above, the power generator 3 of the present invention generates electricity correspondingly via a temperature difference, thereby providing the necessary electricity for the operation of the heat-dissipating fan 5 and thus forming a self-powered heat-dissipating device 10. Therefore, the portable electronic apparatus provided with the heat-dissipating device 10 of the present invention need not to provide additional electricity to the heat-dissipating fan 5, so that the lifetime and standby time of the battery of the portable electronic apparatus can be extended.

To sum up, the present invention achieves the desired objects and solves the drawbacks of prior art. Further, the present invention has not been published or used in public prior to filing. Therefore, the present invention really has novelty and inventive steps and thus conforms to the requirement for a utility model patent.

Although the present invention has been described with reference to the foregoing preferred embodiments, it will be understood that the invention is not limited to the details thereof Various equivalent variations and modifications can still occur to those skilled in this art in view of the teachings of the present invention. Thus, all such variations and equivalent modifications are also embraced within the scope of the invention as defined in the appended claims.

What is claimed is:

1. A heat-dissipating device of a portable electronic apparatus for dissipating heat of a heat-generating element, comprising:
a heat-conducting plate disposed on the heat-generating element;
a heat-conducting pipe, one end thereof being disposed on the heat-conducting plate;
a power generator made of a thermoelectric material capable of converting heat into electricity, one surface of the power generator having a high-temperature heat-conducting piece, the other surface having a low-temperature heat-conducting piece, the high-temperature heat-conducting piece abutting against the other end of the heat-conducting pipe, positive and negative lines extending from an interior of the power generator;
a heat-dissipating body having a plurality of heat-dissipating fins, a flowing path being formed between any two heat-dissipating fins, the heat-dissipating body allowing the low-temperature heat-conducting piece to be disposed thereon; and
a heat-dissipating fan disposed at one side corresponding to the flowing path of the heat-dissipating body, positive and negative lines of the heat-dissipating fan being electrically connected to the positive and negative lines of the power generator.

2. The heat-dissipating device of a portable electronic apparatus according to claim 1, wherein the heat-conducting plate is made of a metallic material.

3. The heat-dissipating device of a portable electronic apparatus according to claim 1, wherein the heat-conducting plate is made of a composite material.

4. The heat-dissipating device of a portable electronic apparatus according to claim 1, wherein the heat-dissipating body is an aluminum-extruded heat-dissipating body.

5. The heat-dissipating device of a portable electronic apparatus according to claim 1, wherein the heat-dissipating body is a laminated heat-dissipating body.

6. The heat-dissipating device of a portable electronic apparatus according to claim 1, wherein the heat-dissipating fan is a centrifugal fan having a blowing port, and the heat-dissipating body is attached on the blowing port.

7. The heat-dissipating device of a portable electronic apparatus according to claim 1, wherein the heat-dissipating fan includes an air-guiding cover and an axial impeller connected to one end of the air-guiding cover, and the heat-dissipating body is attached on one end of the air-guiding cover away from the axial impeller.
